(19) United States
(12) Patent Application Publication
(10) Pub. No.: US 2020/0017957 A1
(43) Pub. Date: Jan. 16, 2020

(54) APPARATUS FOR VACUUM PROCESSING OF A SUBSTRATE, SYSTEM FOR THE MANUFACTURE OF DEVICES HAVING ORGANIC MATERIALS, AND METHOD FOR SEALING AN OPENING CONNECTING TWO PRESSURE REGIONS

(71) Applicants: Sebastian Gunther ZANG, Mainaschaff (DE); Andreas SAUER, Großostheimde (DE); Applied Materials, Inc., Santa Clara, CA (US)

(72) Inventors: Sebastian Gunther ZANG, Mainaschaff (DE); Andreas SAUER, Großostheim (DE)

(21) Appl. No.: 16/485,573

(22) PCT Filed: Mar. 17, 2017
(86) PCT No.: PCT/EP2017/056379

§ 371 Date: Aug. 13, 2019

(51) Int. Cl. C23C 14/56; C23C 16/44; F16K 31/08; H01L 51/56; H01L 51/00

(52) U.S. Cl. CPC C23C 14/562; C23C 16/4409; H01L 51/0011; H01L 51/56; F16K 31/082

(57) ABSTRACT

The present disclosure provides an apparatus (100) for vacuum processing of a substrate (10). The apparatus (100) includes a first vacuum region (110), a second vacuum region (120), an opening (130) between the first vacuum region (100) and the second vacuum region (130), and a closing arrangement (140) for closing the opening (130). The closing arrangement includes one or more first permanent magnets, one or more second permanent magnets, and a magnet device configured to change a magnetization of the one or more first permanent magnets.

### FIELD

Embodiments of the present disclosure relate to an apparatus for vacuum processing of a substrate, a system for the manufacture of devices having organic materials, and a method for sealing an opening connecting two pressure regions. Embodiments of the present disclosure particularly relate to apparatuses, systems and methods used in the manufacture of organic light-emitting diode (OLED) devices.

### BACKGROUND

Techniques for layer deposition on a substrate include, for example, thermal evaporation, physical vapor deposition (PVD), and chemical vapor deposition (CVD). Coated substrates may be used in several applications and in several technical fields. For instance, coated substrates may be used in the field of organic light emitting diode (OLED) devices. OLEDs can be used in the manufacture of television screens, computer monitors, mobile phones, other hand-held devices, and the like for displaying information. An OLED device, such as an OLED display, may include one or more layers of an organic material situated between two electrodes that are all deposited on a substrate.

OLED devices can include a stack of several organic materials, which are for example evaporated in a vacuum chamber of a processing apparatus. The organic materials are deposited on a substrate in a subsequent manner through shadow masks using evaporation sources. The substrate, the shadow masks and the evaporation sources are provided within the vacuum chamber and can be transported between different pressure regions. At least some of the pressure regions, such as vacuum regions, should be sealable from each other, such that gas pressure conditions in one region do not affect e.g. vacuum conditions in another region.

Therefore, there is a need for apparatuses, systems and methods which can provide proper separation of pressure regions of a vacuum system. The present disclosure particularly aims at providing apparatuses, systems and methods that can improve vacuum conditions in a vacuum deposition system.

### SUMMARY

In light of the above, an apparatus for vacuum processing of a substrate, a system for the manufacture of devices having organic materials, and a method for sealing an opening connecting two pressure regions are provided. Further aspects, benefits, and features of the present disclosure are apparent from the claims, the description, and the accompanying drawings.

According to an aspect of the present disclosure, an apparatus for vacuum processing of a substrate is provided. The apparatus includes a first pressure region, a second pressure region, an opening between the first pressure region and the second pressure region, and a closing arrangement for closing the opening. The closing arrangement includes one or more first permanent magnets, one or more second permanent magnets, and a magnet device configured to change a magnetization of the one or more first permanent magnets.

According to another aspect of the present disclosure, a system for the manufacture of devices having organic materials is provided. The system includes the apparatus for vacuum processing of a substrate according to the embodiments described herein, and a transport arrangement configured for contactless transportation of at least one of a substrate carrier and a mask carrier through the opening.

According to a further aspect of the present disclosure, a method for sealing an opening connecting two pressure regions is provided. The method includes changing a magnetization of one or more first permanent magnets to a first magnetization for providing a magnetic force to close the opening.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1A shows a schematic top view of an apparatus for vacuum processing of a substrate according to embodiments described herein;

FIG. 1B shows a schematic top view of an apparatus for vacuum processing of a substrate according to further embodiments described herein;

FIG. 2A shows schematic top views of a closed and an open opening of the apparatus according to embodiments described herein;

FIG. 2B shows a schematic front view of an open opening and a sealing device of the apparatus according to embodiments described herein;

FIG. 3 shows a schematic sequence of closing the opening of the apparatus with a sealing device according to embodiments described herein;

FIGS. 4A and 4B show schematic views of a closing arrangement in a releasing state and a chucking state, respectively, according to embodiments described herein;

FIG. 5 shows a schematic view of a system for the manufacture of devices having organic materials according to embodiments described herein;

FIGS. 6A and B show schematic views of an exemplary transport arrangement for transporting a carrier in a vacuum system according to embodiments described herein; and

FIG. 7 shows a flowchart of a method for sealing an opening connecting two pressure regions according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

A vacuum system can include various pressure regions for providing various tasks, such as material deposition on a substrate, substrate handling, mask handling, loading, and the like. As an example, masks can be transferred between substrate processing regions and routing regions for routing the masks to the correct processing region. At least some of the pressure regions should be sealable from each other such that gas pressure conditions in one region do not affect e.g. vacuum conditions in another region. In particular, by improving vacuum conditions in the processing regions, an improved quality, such as purity, of the layers deposited on the substrates can be achieved.

The present disclosure provides an opening connecting two adjacent pressure regions, wherein the opening is closeable by changing a magnetization of one or more first permanent magnets. As an example, a sealing device can cover the opening, wherein the sealing device can be magnetically held at the opening to seal the opening. The magnetic sealing can reduce a number of mechanically movable parts in the vacuum system. A generation of particles due to such mechanically movable parts can be reduced and e.g. a quality of the material layers deposited on the substrate can be improved. Further, a reliable closing of the opening can be provided also in the case of a power failure, because the opening is sealed by a magnetic force generated by permanent magnets. No external power may be needed for maintaining the sealed state.

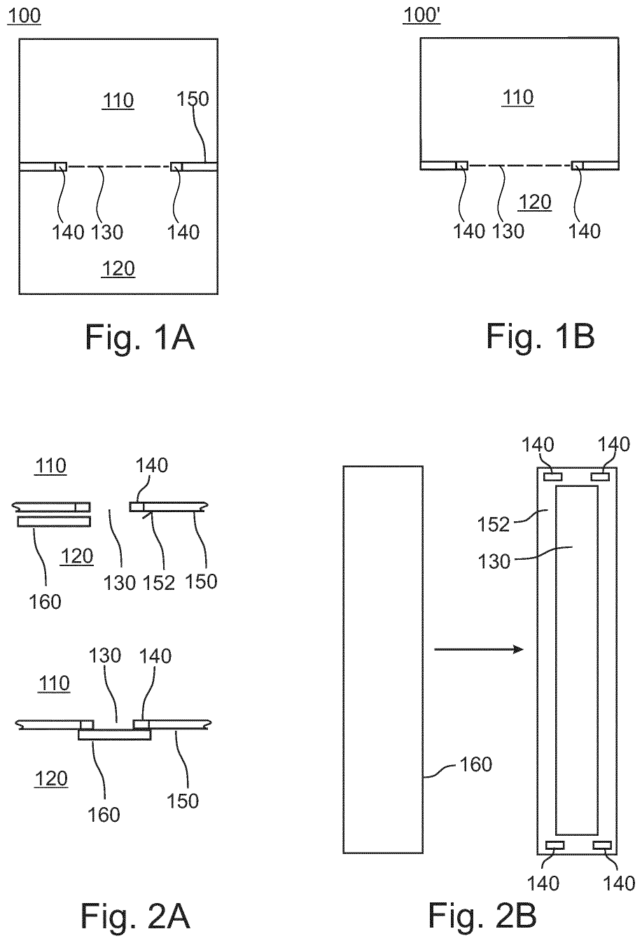

FIG. 1A shows a schematic top view of an apparatus 100 for vacuum processing of a substrate according to embodiments described herein. FIG. 1B shows a schematic top view of an apparatus 100′ for vacuum processing of a substrate according to further embodiments described herein. The apparatuses can be configured for deposition of layers of an organic material on a substrate, for example, to manufacture OLED devices.

The apparatus 100 includes a first pressure region 110, a second pressure region 120, an opening 130 between the first pressure region 110 and the second pressure region 120, and a closing arrangement 140 for closing the opening 130. The closing arrangement 140 includes one or more first permanent magnets, one or more second permanent magnets, and a magnet device configured to change a magnetization of the one or more first permanent magnets. The closing arrangement 140 can be provided at the opening 130. The apparatus 100 can further include a sealing device, such as a sealing plate, configured for closing the opening 130. An exemplary sealing device is explained with respect to FIGS. 2A and B.

A reliable closing of the opening 130 e.g. using the sealing device can be provided also in the case of a power failure, because the opening 130 is sealed by a magnetic force generated by permanent magnets. In the holding state, no external power may be needed for maintaining the sealed state.

The first pressure region 110 and the second pressure region 120 are connected via the sealable opening. According to some embodiments, which can be combined with other embodiments described herein, the opening 130 can be configured for a passage of devices from the first pressure region 110 to the second pressure region 120 and/or from the second pressure region 120 to the first pressure region 110. As an example, the opening 130 can be configured for a passage of a mask, a mask carrier, a substrate, a substrate carrier, and any combination thereof.

The first pressure region 110 and the second pressure region 120 can be selected from the group consisting of a vacuum region and an atmospheric region. As exemplarily illustrated in FIG. 1A, the first pressure region 110 is a first vacuum region and the second pressure region 120 is a second vacuum region. In another example illustrated in FIG. 1B, the first pressure region 110 is a first vacuum region and the second pressure region 120 is an atmospheric region.

As used throughout the present disclosure, a vacuum region can be understood in the sense of a region of a technical vacuum having a vacuum pressure of less than, for example, 10 mbar. The pressure in a vacuum region may be between 10⁻⁵ mbar and about 10⁻⁸ mbar, specifically between 10⁻⁵ mbar and 10⁻⁷ mbar, and more specifically between about 10⁻⁶ mbar and about 10⁻⁷ mbar. Similarly, an atmospheric region is a region of atmospheric pressure. The atmospheric region can be provided at an atmospheric side of the vacuum system.

According to some embodiments, which can be combined with other embodiments described herein, the apparatus 100 includes a first vacuum chamber and a second vacuum chamber, wherein the first pressure region 110 is provided by the first vacuum chamber and the second pressure region 120 is provided by the second vacuum chamber. In other words, the apparatus 100 can have two separate vacuum chambers, wherein each of the two chambers provides one of the pressure regions. The vacuum chambers can be connected to each other. The connection between the vacuum chambers includes the opening 130.

According to further embodiments, which can be combined with other embodiments described herein, the apparatus 100 includes a first vacuum chamber providing the first pressure region 110 and the second pressure region 120. In other words, the first pressure region 110 and the second pressure region 120 can be provided within the same vacuum chamber.

In some implementations, the vacuum chamber includes a partition 150 separating the first pressure region 110 and the second pressure region 120 from each other. The partition 150 can be a chamber wall of the first vacuum chamber and/or the second vacuum chamber. The opening 130 can be provided in the partition 150.

According to yet further embodiments, which can be combined with other embodiments described herein, the apparatus includes a first vacuum chamber providing the first pressure region 110, wherein the second pressure region 120 is an atmospheric region, i.e., a region of atmospheric pressure. This is exemplarily illustrated in FIG. 1B. The opening 130 can for instance be provided in an external chamber wall of the first vacuum chamber.

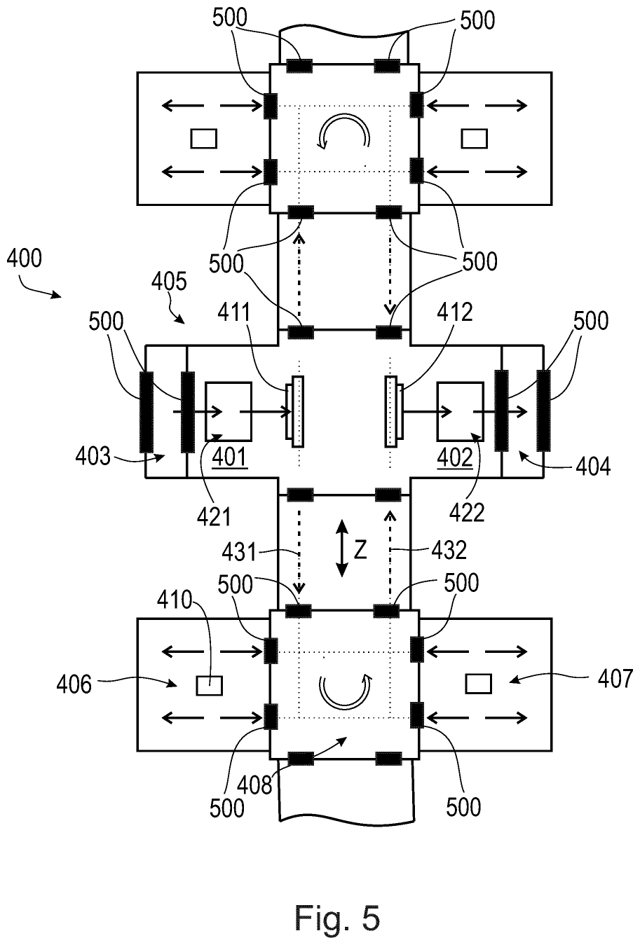

In some implementations, at least one of the first vacuum chamber and the second vacuum chamber are selected from the group consisting of a processing vacuum chamber, a transit module, a routing module, a maintenance vacuum chamber, a load lock chamber, a buffer chamber, a swing module, and a storage chamber. Examples are further explained with respect to FIG. 5.

FIG. 2A shows schematic top views of a closed and an open opening of the apparatus according to embodiments described herein. FIG. 2B shows a schematic front view of the open opening and a sealing device.

According to some embodiments, which can be combined with other embodiments described herein, the apparatus, and particularly the closing arrangement 140, includes the sealing device 160 configured for closing the opening 130. The sealing device 160 can be configured to cover the opening 130. As an example, the sealing device 160 can be a sealing plate configured to cover and seal the opening 130. The closing arrangement 140 can be configured to magnetically hold the sealing device 160 at the opening 130, and particularly at a holding surface 152 at least partially surrounding the opening 130. The holding surface 152 can also be referred to as “sealing surface”.

Referring to the upper part of FIG. 2A, the opening 130 is open and the sealing device 160 is in a released state. In other words, the sealing device 160 is not held by the closing arrangement 140. Devices, such as a mask, a mask carrier, a substrate, and/or a substrate carrier, can move through the opening 130 from one pressure region to another pressure region. For closing the opening 130, the sealing device 160 may move to cover the opening 130. As an example, the sealing device 160 can linearly move e.g. in a horizontal direction and/or a vertical direction to cover the opening 130, as is illustrated in FIG. 2B. The magnet device of the closing arrangement 140 can change the magnetization of the one or more first permanent magnets to provide a magnetic force acting on the sealing device 160, such that the sealing device 160 is attracted towards and held at the opening 130 to seal the opening 130. According to some embodiments, which can be combined with other embodiments described herein, the sealing device 160 is configured to seal the opening 130 essentially vacuum-tight.

According to some embodiments, which can be combined with other embodiments described herein, the apparatus includes the partition 150, which may be a chamber wall or a separate element configured to separate the first pressure region 110 and the second pressure region 120 from each other. The partition 150 can for instance be a chamber wall of a processing vacuum chamber. The opening 130 can be provided in the partition 150.

In some implementations, at least a portion of the closing arrangement 140 can be provided at the opening 130. As an example, the closing arrangement 140 can be provided adjacent to the opening 130, e.g., at or in the partition 150. The closing arrangement 140 can be configured for attracting the sealing device 160, such as a sealing plate, towards the opening 130, e.g., the holding surface 152.

According to some embodiments, the apparatus includes the holding surface 152 at the opening 130. In some implementations, the holding surface 152 can at least partially, and preferably entirely, surround the opening 130, as is exemplarily illustrated in FIG. 2B. The holding surface 152 can be provided by the partition 150, e.g., adjacent to the opening 130. As an example, the holding surface 152 can be configured to contact a surface, such as a contact surface, of the sealing device 160. One or more sealing elements, such as O-rings, can be provided at the holding surface 152, such that the opening 130 can be sealed essentially vacuum-tight.

According to some embodiments, which can be combined with other embodiments described herein, the opening 130 can be a slit. A slit can be a narrow opening, which can for instance allow a passage of a vertically oriented carrier, such as a mask carrier and/or a substrate carrier. The slit can have a first dimension, such as a height, larger than a second dimension, such as a width. The first dimension can be a vertical extension, and the second dimension can be a horizontal dimension. By minimizing an area of the opening, a separation of the first pressure region and the second pressure region can be improved.

According to some embodiments, the sealing device 160 can include, or be made of, a magnetic material. The magnetic field generated by the closing arrangement 140 can act on the magnetic material to provide the magnetic force attracting the sealing device 160 towards the opening 130, and particularly towards the holding surface 152. In some implementations, the magnetic material can be selected from the group consisting of iron, steel, stainless steel, a ferromagnetic material, a ferrimagnetic material, a diamagnetic material, and any combination thereof.

According to further embodiments, the sealing device 160 can include one or more magnet elements. The one or more magnet elements can be located corresponding to the closing arrangement 140, such that the magnetic field generated by the closing arrangement 140 can act on the one or more magnet elements to provide the magnetic force attracting the sealing device 160 towards the opening 130, and particularly towards the holding surface 152. The one or more magnet elements can be permanent magnets attached to, or integrated in, the sealing device 160. In such a case, the sealing device 160 can be made of a non-magnetic material, such as aluminum.

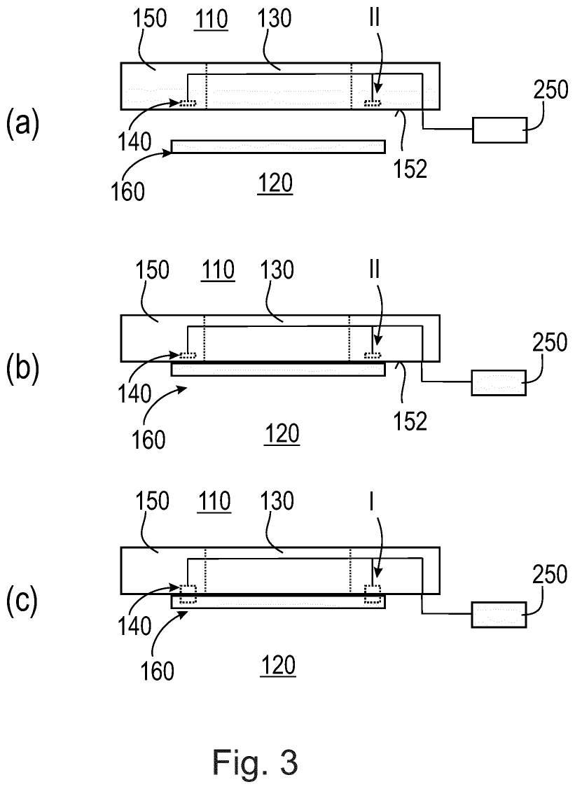

FIG. 3 is a schematic illustration of subsequent stages (a), (b), (c) for closing the opening 130 to seal the first pressure region 110 and the second pressure region 120 from each other. Although the sealing device is shown as being located in the second pressure region, the present disclosure is not limited thereto, and the sealing device can also be provided in the first pressure region. In further implementations, two sealing devices can be provided for sealing the opening, one in the first pressure region 110 and another one in the second pressure region 120.

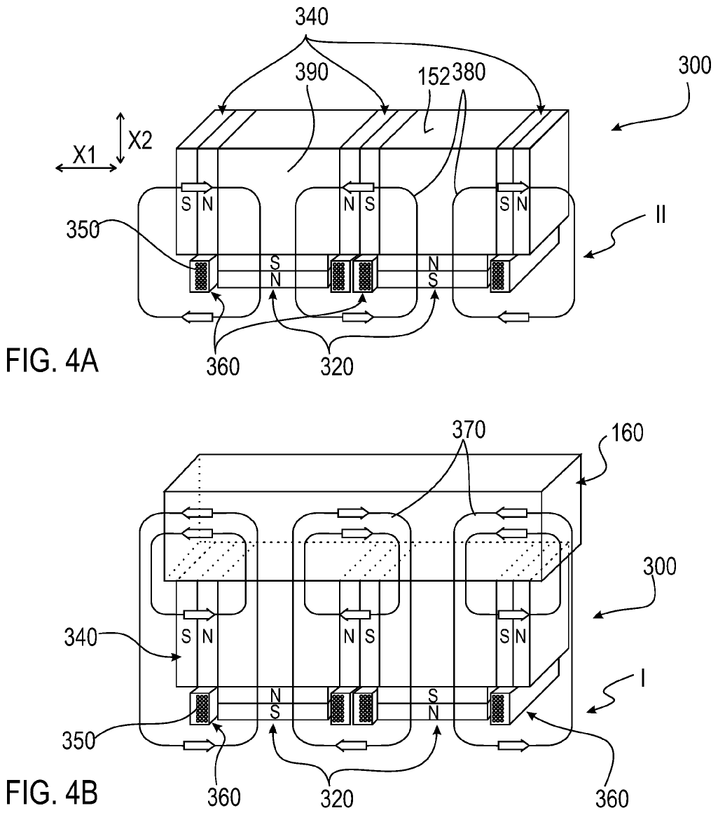

The apparatus for vacuum processing of a substrate according to the present disclosure includes the closing arrangement 140 for magnetically closing the opening 130. The closing arrangement 140 can also be referred to as “magnetic closing arrangement”. “Magnetically closing” as used throughout the present disclosure can be understood in the sense that a magnetic force is used to seal the opening 130, e.g., essentially vacuum-tight. As an example, the sealing device 160 can be configured to cover the opening 130, wherein the closing arrangement 140 can be configured to hold the sealing device 160 at the opening 130 using a magnetic force. The closing arrangement 140 can include, or be, an electropermanent magnet arrangement. The electropermanent magnet arrangement is further explained with respect to FIGS. 4A and B.

Turning now to FIG. 3, in a stage (a), the sealing device 160 is moved towards the opening 130, e.g., the holding surface 152. As an example, the sealing device 160 can perform an essentially linear movement towards the opening 130. In some embodiments, which may be combined with other embodiments described herein, the closing arrangement 140 may be switchable between a chucking state I and a releasing state II. In the releasing state II, the closing arrangement 140 may generate no external magnetic field or a small external magnetic field at the holding surface 152. In the chucking state I, the closing arrangement 140 may generate a strong external magnetic field at the holding surface 152. In other words, a second external magnetic field at the holding surface 152 in the releasing state II may be smaller than a first external magnetic field at the holding surface 152 in the chucking state I.

The first external magnetic field may be sufficient to hold the sealing device 160 at the opening 130. In some implementations, the closing arrangement 140 can be configured to provide a force of 10 N/cm² or more, specifically 50 N/cm² or more, specifically 100 N/cm² or more, and more specifically 150 N/cm² or more. The force can be the magnetic force acting on the sealing device 160 to hold the sealing device 160 at the opening 130, and particularly at the holding surface 152.

In stage (a) of FIG. 3, the closing arrangement 140 is provided in the releasing state II in which the closing arrangement 140 may generate no external magnetic field or only a small external magnetic field at the holding surface 152. Accordingly, the sealing device 160 is not attracted towards the holding surface 152.

In stage (b) of FIG. 3, the sealing device 160 has moved to be in contact with the partition 150. The closing arrangement 140 is still in the releasing state II in which the sealing device 160 is not held at the holding surface 152 by a magnetic force of the closing arrangement 140.

In stage (c) of FIG. 3, the closing arrangement 140 has switched to the chucking state I. In the chucking state I, the magnetic field generated by the closing arrangement 140 holds the sealing device 160 at the holding surface 152. The first pressure region 110 and the second pressure region 120 can be sealed from each other essentially vacuum-tight.

Similarly, the sealing device 160 can be detached e.g. from the partition 150 by switching the closing arrangement 140 from the chucking state I to the releasing state II in which no external magnetic field or only a small external magnetic field is generated at the holding surface 152, as is depicted in stage (b) of FIG. 3. The sealing device 160 can then be removed from the opening 130 such that e.g. a mask carrier and/or a substrate carrier can be moved through the opening 130.

The closing arrangement 140 may be switched between the releasing state I and the chucking state II by changing a direction of magnetization of one or more first permanent magnets of the closing arrangement 140, e.g. by an electric pulse provided to the magnet device of the closing arrangement 140. In particular, a polarity of the one or more first permanent magnets may be reversed by an electric pulse sent to the magnet device. In some embodiments, the apparatus includes a power supply 250 for the closing arrangement 140. The power supply 250 can be configured to generate an electric pulse, e.g. a current pulse, which may be suitable for changing the magnetization of the one or more first permanent magnets. This is further explained with respect to FIGS. 4A and B.

FIG. 4A is a schematic view of a closing arrangement 300 according to embodiments described herein in a releasing state II. FIG. 4B is a schematic view of the closing arrangement 300 of FIG. 4A in a chucking state I in which a device, e.g. the sealing device 160, is held by the closing arrangement 300.

The closing arrangement 300 may be configured as an electropermanent magnet arrangement. The electropermanent magnet arrangement includes the one or more first permanent magnets 320, one or more second permanent magnets 340, and the magnet device 360. The electropermanent magnet arrangement uses two magnetic planes that are oriented with respect to each other at an angle of about 90°.

In more detail, an electropermanent magnet arrangement (or “EPM”) as used herein may be understood as a magnet arrangement in which a magnetic field generated by permanent magnets can be changed by an electric pulse, particularly by a current pulse in a winding of the magnet device 360. In particular, the magnetic field may be switched on or off on one side of the closing arrangement 300 where the holding surface 152 is provided. Electropermanent magnets may work based on the double magnet principle. The one or more first permanent magnets 320 may consist of a “soft” or “semi-hard” magnetic material, i.e. a material with a low coercivity. The one or more second permanent magnets 340 may consist of a “hard” magnetic material, i.e. a material with a higher coercivity. The direction of magnetization of the one or more first permanent magnets 320 can be changed by an electric pulse provided to the magnet device 360. As an example, a polarity of the one or more first permanent magnets 320 can be reversible by the electric pulse. The direction of magnetization of the one or more second permanent magnets 340 may remain constant due to the high coercivity of the respective material.

The polarity of the one or more first permanent magnets 320 and the polarity of the one or more second permanent magnets 340 are magnetic polarities, i.e., magnetic south poles and magnetic north poles.

According to some embodiments, a duration of the electric pulse to change the magnetization of the one or more first permanent magnets 320 is 0.1 s or more, specifically is or more, and more specifically 3 s or more. As an example, the duration of the electric pulse is in a range between 0.1 and 10 s, specifically in a range between 0.5 and 5 s, and more specifically in a range between 1 and 2 s.

In some embodiments, the magnet device 360 may include a winding 350, e.g. a wire winding or solenoid that is provided at least partially around the one or more first permanent magnets 320. By supplying an electric pulse through the winding 350, a local magnetic field at the position of the one or more first permanent magnets 320 is generated which changes the magnetization of the one or more first permanent magnets 320. In particular, a polarity of the one or more first permanent magnets 320 may be reversed by feeding a current pulse through the winding 350 of the magnet device 360.

In some embodiments, a plurality of first permanent magnets is provided, wherein the first permanent magnets are at least partially surrounded by windings of the magnet device 360. For example, in the embodiment of FIG. 4A, two first permanent magnets are depicted, wherein a wire winding extends around each of the two first permanent magnets. More than two first permanent magnets may be arranged next to each other. In some embodiments, the polarities of two adjacent first permanent magnets directed toward the holding surface 152 may be opposite polarities, respectively. Accordingly, the magnetic field lines may form one or more loops, wherein each loop penetrates through adjacent first permanent magnets in opposite directions.

In some embodiments, a plurality of second permanent magnets is provided. For example, in the embodiment of FIG. 4A, three second permanent magnets are depicted. Two, three or more second permanent magnets may be provided, e.g. one after the other in a row arrangement. The second permanent magnets may be arranged such that poles of opposite polarities of adjacent second permanent magnets may be directed toward each other. Accordingly, the magnetic field lines do not linearly extend through the row of second permanent magnets, but a plurality of separate loops may form due to the opposite poles facing each other.

In some embodiments, the one or more first permanent magnets 320 may be arranged in a first plane, and the one or more second permanent magnets 340 may be arranged in a second plane. The second plane may be closer to the holding surface 152 than the first plane. Accordingly, the one or more second permanent magnets 340 may be arranged closer to the holding surface 152 than the one or more first permanent magnets 320.

In some embodiments, the one or more first permanent magnets 320 may have a first orientation and the one or more second permanent magnets 340 may have a second orientation different from the first orientation. In particular, the first orientation and the second orientation may be perpendicular. For example, the one or more first permanent magnets 320 may be oriented in a horizontal direction or plane and the one or more second permanent magnets 340 may be oriented in a vertical orientation or plane.

In some embodiments, the magnetic field generated by the one or more second permanent magnets 340 may have a first main orientation X1 which can be essentially parallel to the holding surface 152. The magnetic field generated by the one or more first permanent magnets 320 may have a second main orientation X2 which can be essentially perpendicular to the holding surface 152. Accordingly, by reversing the polarities of the one or more first permanent magnets 320, the resultant total magnetic field may change in a direction perpendicular to the holding surface 152, i.e. toward an interior of the sealing device 160 or toward an exterior of the sealing device 160. By switching the closing arrangement 300 from the releasing state II of FIG. 4A to the chucking state I of FIG. 4B, the resultant overall magnetic field can be shifted to an exterior of the holding surface 152 such as to penetrate into a device to be attached. In particular, in the chucking state I, opposite poles of the one or more first permanent magnets 320 and of the one or more second permanent magnets 340 may be facing each other such that the magnetic field lines may be urged toward an outer environment of the holding surface 152 where the device to be attached is arranged.

The external magnetic field 370 which penetrates into the sealing device 160 is schematically depicted in FIG. 4B. The external magnetic field 370 remains in the sealing device 160 until the polarity of the one or more first permanent magnets 320 is reversed by an electric pulse. The chucked sealing device can be released by providing an electric pulse to the magnet device 360. A reliable attachment of the sealing device 160 can be obtained also in the case of a power failure, because the sealing device 160 is held by a magnetic force generated by permanent magnets. In the chucking state I, no external power may be needed for maintaining the chucked state. No heat due to continuously operating electric devices is generated and an additional cooling is not needed to maintain process stability. A bistable magnet arrangement can be provided which remains in the releasing state II or in the chucking state I after switching. The switching can be performed automatically.

The internal magnetic field 380 that is generated by the closing arrangement 300 in the releasing state II is schematically depicted in FIG. 4A. A core 390 such as a steel core may be provided for increasing the magnetic field strength, e.g. between adjacent second permanent magnets, respectively.

In some embodiments, which may be combined with other embodiments described herein, the one or more first permanent magnets 320 include a soft or semi-hard magnetic material, and/or the one or more second permanent magnets 340 include a hard magnetic material. For example, the one or more first permanent magnets 320 may include AlNiCo and/or the one or more second permanent magnets 340 may include neodymium. In particular, the one or more first permanent magnets 320 may be AlNiCo-magnets, and/or the one or more second permanent magnets 340 may be neodymium-magnets. Other magnets with low and high coercivities may be used. For example, the hard magnetic material may have a coercivity of 1.000 kA/m or more, particularly 10.000 kA/m or more, and/or the soft magnetic material may have a coercivity of 1.000 kA/m or less, particularly 100 kA/m or less.

FIG. 5 shows a schematic view of a system 400 for the manufacture of devices having organic materials according to embodiments described herein. In the following, the system 400 is also referred to as “vacuum system”.

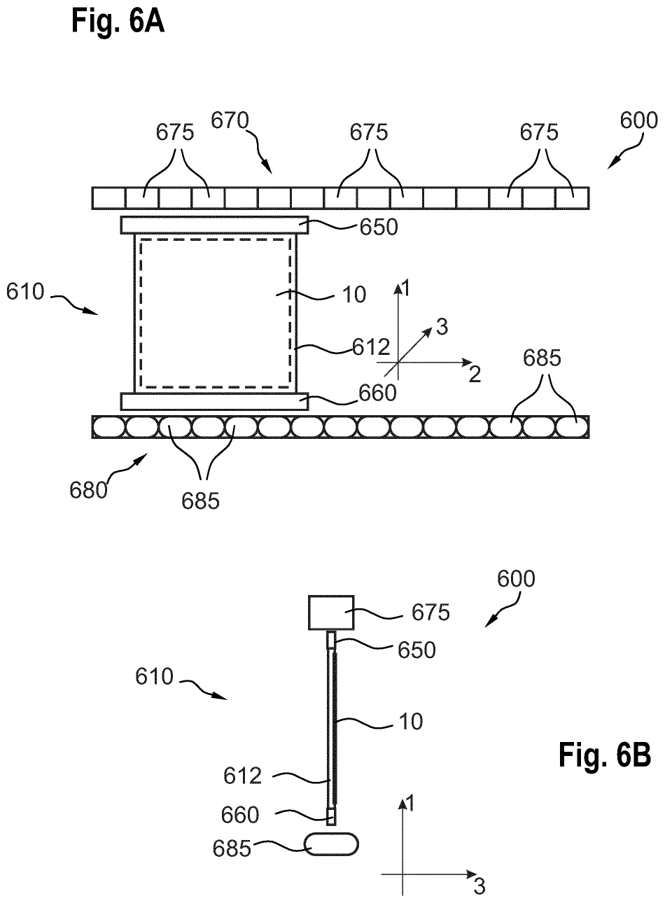

The system 400 can include the apparatus for vacuum processing of a substrate according to the embodiments described herein and a transport arrangement configured for contactless transportation of at least one of a substrate carrier and a mask carrier at least through the opening. The transport arrangement is further explained with respect to FIGS. 6A and B.

The system 400 can include a plurality of pressure regions. The plurality of pressure regions can be provided either by one single vacuum chamber or by multiple vacuum chambers connected to each other. The plurality of pressure regions can include one or more vacuum regions and/or one or more atmospheric regions. The transport arrangement can be configured for transportation of the mask carrier and/or the substrate carrier within the system 400.

In some examples, the opening, the closing arrangement and optionally the sealing device can be included in a valve connecting adjacent pressure regions. The valve can be configured for opening and closing the vacuum seal between the pressure regions. The substrate carrier and/or the mask carrier can be transferred from one pressure region to another pressure region while the valve is in an open state, i.e., while the opening is open/uncovered. Thereafter, the valve can be magnetically closed to provide the vacuum seal between the adjacent pressure regions. When the valve is closed, the pressure regions are sealed from each other such that pressure and/or gas conditions in one pressure region do not affect pressure and/or gas conditions in the other pressure region.

Turning now to FIG. 5, the system 400 includes a mask handling chamber 405 and at least one deposition chamber, such as a first deposition chamber 406 and a second deposition chamber 407. The first deposition chamber 406 and the second deposition chamber 407 may be arranged on the same side of the mask handling chamber 405, e.g. on the lower side in FIG. 5. In some embodiments, further deposition chambers may be arranged on the other side of the mask handling chamber 405, e.g. on the upper side in FIG. 5.

The mask handling chamber 405 can include a first mask handling area 401 with a first mask handling assembly 421 configured for handling mask devices to be used 411 and a second mask handling area 402 with a second mask handling assembly 422 configured for handling used mask devices 412.

“Mask devices to be used” as used herein may be understood as masks that are to be transported into at least one deposition chamber to be used for masked deposition on a substrate. In some embodiments, a mask device to be used may be a new mask device, a cleaned mask device or a mask device that has undergone service or maintenance. “Used mask devices” as used herein can be understood as masks that have been used for masked deposition in a deposition chamber. The used mask devices are to be transported out of the deposition chamber, e.g. for cleaning or maintenance. For example, the used mask devices are to be unloaded from the vacuum system, e.g. for cleaning under atmospheric pressure. By using a mask device for masked deposition on one or more substrates, a mask device to be used becomes a used mask device. Typically, a mask device is used for masked deposition on ten or more substrates, whereupon the mask device may be cleaned. After cleaning, the mask device can be loaded again into the vacuum system to be used for masked deposition.

The second mask handling area 402 and the first mask handling area 401 may correspond to different sections of the mask handling chamber 405 that may be adjacent to each other or that may be spaced apart from each other. For example, the first mask handling area 401 and the second mask handling area 402 may be opposite parts of the mask handling chamber. In some embodiments, the first mask handling area 401 and the second mask handling area 402 are located on opposite sides of transport paths configured for the transport of the mask carriers. For example, the first mask handling area 401 may be located on a first side of first and second mask tracks and the second mask handling area 402 may be located on the opposite side of the first and second mask tracks.

According to some embodiments described herein, the mask devices to be used 411 can be handled, e.g. attached, detached, loaded, unloaded, stored, moved, rotated and/or translated, separately from the used mask devices 412. A contamination of cleaned mask devices can be reduced or avoided.

According to some embodiments, which can be combined with other embodiments described herein, a mask loading passage which extends to the first mask handling area 401 and a mask unloading passage which extends from the second mask handling area 402 may be provided. The mask loading passage may be spaced apart from the mask unloading passage. For example, the mask loading passage and the mask unloading passage may be provided on opposite sides of transport paths configured for the transport of the mask carriers. The mask loading passage may extend to the first mask handling area 401 and may be configured for loading the mask devices to be used 411 into the vacuum system, e.g. via a first load lock chamber 403. The mask unloading passage may extend from the second mask handling area 402 and may be configured for unloading the used mask devices 412 from the vacuum system, e.g. via a second load lock chamber 404.

In some embodiments, which may be combined with other embodiments described herein, the first mask handling assembly 421 may be configured for attaching the mask devices to be used 411 to mask carriers. In some embodiments, which may be combined with other embodiments described herein, the second mask handling assembly 422 may be configured for detaching the used mask devices 412 from the mask carriers 415.

By providing the first mask handling assembly 421 and the second mask handling assembly 422 for handling the mask devices in different areas of the vacuum system, the mask traffic within the vacuum system can be simplified and the mask handling can be accelerated. In particular, different areas within the mask handling chamber may be provided for handling the used mask devices and the mask devices to be used. This may reduce the complexity of the mask traffic in the vacuum system.

The complexity of the mask traffic in the vacuum system may be further reduced by providing a mask transportation system that includes a first mask track 431 for guiding mask carriers that hold mask devices to be used 411 from the first mask handling area 401 toward the at least one deposition chamber, and/or that includes a second mask track 432 for guiding mask carriers that hold used mask devices 412 to the second mask handling area 402 from the at least one deposition chamber.

By providing different mask tracks for mask devices to be used in the first mask handling area and for used mask devices in the second mask handling area, the first mask handling assembly 421 and the second mask handling assembly 422 may be operated independently. For example, a mask device may be attached to a mask carrier arranged on the first mask track 431 and a further mask device may be detached from a further mask carrier arranged on the second mask track 432, e.g. at the same time or subsequently. The mask devices can be handled quicker and more flexibly.

In some embodiments, which may be combined with other embodiments described herein, the mask transportation system may further include a translation mechanism configured for translating mask carriers within the mask handling chamber 405 from the second mask track 432 to the first mask track 431 and/or vice versa. Accordingly, a mask carrier can be directly translated from the second mask handling area 402 into the first mask handling area 401. A direct transfer of an empty mask carrier may be useful when a used mask device was detached from the mask carrier in the second mask handling area, and a new mask device is to be attached to the mask carrier in the first mask handling area 401. Accordingly, an empty mask carrier can be used for transporting a further mask device. The transport path lengths for the mask carriers can be reduced and the mask traffic in the vacuum system can be accelerated.

A translation mechanism may be understood as a mechanism that is configured for translating a mask carrier between the first mask track 431 and the second mask track 432 in the mask handling chamber 405. For example, the mask carrier may be linearly moved between the first mask track 431 and the second mask track 432 in a direction that may be transverse or perpendicular to the directions of the first and second mask tracks.

Accordingly, in some embodiments, at least one loop transport path for the mask carriers may be provided. Namely, a mask device to be used may be attached to a mask carrier in the first mask handling area 401, the mask carrier may be transported along the first mask track 431 toward the at least one deposition chamber, the mask carrier may be transported along the second mask track 432 back to the mask handling chamber into the second mask handling area 402, and the used mask device may be detached from the mask carrier in the second mask handling area 402. Thereupon, in some embodiments, the (empty) mask carrier may be directly translated within the mask handling chamber into the first mask handling area with the translation mechanism, where a further mask device to be used may be attached to the mask carrier. The mask traffic can be simplified and carrier jams or interference between the mask carriers can be reduced.

The mask handling chamber 405 may be provided in a main transportation path Z of the vacuum system which extends in a main transport direction (e.g. up-down direction in FIG. 5). Substrate tracks for transporting substrate carriers and mask tracks for transporting mask carriers may run through the mask handling chamber 405 in the main transport direction of the vacuum system. The substrates may be transported through the mask handling chamber 405 one or more times for being coated with a material stack, e.g. when two or more deposition chambers are arranged on different sides of the mask main transportation path Z.

By inserting the mask handling chamber 405 into the main transportation path Z of the vacuum system, the mask handling chamber 405 may be used for the handling of mask devices that are used in two or more deposition chambers, particularly three or more deposition chambers, more particularly four or more deposition chambers. In some embodiments, at least two deposition chambers that are supplied with mask devices from the mask handling chamber are arranged on different sides of the mask handling chamber. Alternatively or additionally, at least two deposition chambers that are supplied with mask devices from the mask handling chamber are arranged on the same side of the mask handling chamber. In the latter case, a routing chamber 408 or routing module may be provided for routing the mask devices into the correct deposition chamber.

In some embodiments, which may be combined with other embodiments described herein, the main transportation path Z of the vacuum system includes four or more tracks, including a first mask track 431, a second mask track 432, a first substrate track and a second substrate track. Further tracks may be provided. The tracks may extend parallel to each other in the main transport direction of the vacuum system. The first substrate track and the second substrate track may be provided as outer tracks, and the first mask track 431 and the second mask track 432 may be provided as inner tracks that are arranged between the substrate tracks. Other arrangements are possible.

In some embodiments, said four or more tracks of the main transportation path Z may extend through the mask handling chamber 405, e.g. essentially parallel to each other. The first mask handling assembly 421 may be configured for handling a mask device that is held by a mask carrier on the first mask track 431 in the mask attaching position. The second mask handling assembly 422 may be configured for handling a mask device that is held by a mask carrier on the second mask track 432 in the mask detaching position.

In some embodiments, which may be combined with other embodiments described herein, the transportation arrangement can be further configured for transporting substrates along a substrate transportation path in the vacuum system. In particular, the substrate transportation path may extend through the mask handling chamber 405 or past the mask handling assembly. A substrate can be transported along the substrate transportation path through the mask handling chamber 405, e.g. from a first deposition chamber which is arranged on a first side of the mask handling chamber to a second deposition chamber which is arranged on a second side of the mask handling chamber.

In some embodiments, which can be combined with other embodiments described herein, the vacuum system may further include a routing chamber 408. The routing chamber 408 can be arranged between the mask handling chamber 405 and the at least one deposition chamber. The routing chamber 408 may include a routing device, e.g. a rotation device, configured for routing mask devices to be used 411 and the used mask devices 412 between the mask handling chamber 405 and the at least one deposition chamber. For example, an orientation of the at least one deposition chamber may be perpendicular with respect to a main transportation path Z of the vacuum system, so that the mask carriers and the substrate carriers are to be rotated around an essentially vertical axis at an intersection between the main transportation path Z and the deposition chambers. The mask carriers and/or the substrate carriers may be rotated in the routing chamber 408.

In some embodiments, further deposition chambers, transition chambers and/or routing chambers may be provided on the other side of the mask handling chamber 405, e.g. on the upper side in FIG. 5. The mask handling chamber 405 may be configured for supplying each of said deposition chambers with mask devices to be used and for handling the used mask devices from each of said deposition chambers. The complexity of the mask traffic in a vacuum system can be reduced and the mask exchange can be accelerated.

In some embodiments, an evaporation source 410 may be provided in the at least one deposition chamber for masked deposition of a material on the substrate. The present disclosure is however not restricted to vacuum systems with an evaporation source. For example, chemical vapor deposition (CVD) systems, physical vapor deposition (PVD) systems, e.g. sputter systems, and/or evaporation systems were developed to coat substrates, e.g. thin glass substrates, e.g. for display applications, in a deposition chamber. In typical vacuum systems, the substrates may be held by substrate carriers, and the substrate carriers may be transported through the vacuum chamber by a substrate transport system. The substrate carriers may be moved by the substrate transport system such that at least a part of the main surfaces of the substrates are exposed toward coating devices, e.g. a sputter device or an evaporation source. The main surfaces of the substrates may be coated with a thin coating layer, while the substrates may be positioned in front of an evaporation source 410 which may move past the substrate at a predetermined speed. Alternatively, the substrate may be transported past the coating device at a predetermined speed.

According to some embodiments, which can be combined with other embodiments described herein, one or more magnetically sealable openings of the apparatus of the present disclosure can be provided at various locations of the system 400. In particular, the system 400 can include one or more vacuum chambers selected from the group including a processing vacuum chamber (e.g., the at least one deposition chamber), a transit module, a routing module, a maintenance vacuum chamber, a load lock chamber, a buffer chamber, a swing module, and a storage chamber. The magnetically sealable opening can be provided between two adjacent vacuum chambers for sealing the vacuum chambers from each other. Optionally or alternatively, one or more magnetically sealable openings can be provided within one or more vacuum chambers of the system to provide two or more sealable pressure regions within each vacuum chamber.

As an example, one or more magnetically sealable openings 500 can be provided between at least one of:
(i) the routing module and the at least one deposition chamber,
(ii) the mask handling chamber and the routing module,
(iii) the routing module and a transit module (not shown, may be included in the routing module),
(iv) a load lock chamber and the mask handling chamber (e.g. between the first load lock chamber 403 and the first mask handling area 401 and/or between the second load lock chamber 404 and the second mask handling area 402),
(v) a load lock chamber (e.g. the first load lock chamber 403 and the second load lock chamber 404) and an atmospheric side (e.g., a mask supply storage),
(vi) the routing module and a swing module (not shown),
(vii) a (mask and/or substrate) buffer and the swing module, and/or
(viii) a (mask and/or substrate) buffer and the routing module.

The locations of the magnetically sealable opening are not limited to the above examples, and the magnetically sealable opening 500 can be provided at further locations of the vacuum system of the present disclosure. As an example the magnetically sealable opening can be provided at two sides of a load lock chamber, such as the first load lock chamber 403 and/or the second load lock chamber 404, for loading/unloading substrates into/out of the vacuum system. In another example, the magnetically sealable opening can be provided on both sides of a vacuum swing module which is arranged next to a substrate load lock chamber.

The transit module can include crossing tracks such that carrier(s) can be transferred through the transit module in different directions, e.g., directions perpendicular to each other. The swing module may be configured to change an orientation of a substrate, a substrate carrier, a mask, and/or a mask carrier e.g. from essentially horizontal to essentially vertical, or vice versa. A “processing vacuum chamber” is to be understood as a vacuum chamber or the deposition chamber. The term “vacuum”, as used herein, can be understood in the sense of a technical vacuum having a vacuum pressure of less than, for example, 10 mbar. The pressure in a vacuum chamber as described herein may be between 10⁻⁵ mbar and about 10⁻⁸ mbar, specifically between 10⁻⁵ mbar and 10⁻⁷ mbar, and more specifically between about 10⁻⁶ mbar and about 10⁻⁷ mbar. According to some embodiments, the pressure in the vacuum chamber may be considered to be either the partial pressure of the evaporated material within the vacuum chamber or the total pressure (which may approximately be the same when only the evaporated material is present as a component to be deposited in the vacuum chamber). In some embodiments, the total pressure in the vacuum chamber may range from about 10⁻⁴ mbar to about 10⁻⁷ mbar, especially in the case that a second component besides the evaporated material is present in the vacuum chamber (such as a gas or the like).

According to some embodiments, which can be combined with other embodiments described herein, the carriers are configured for holding or supporting the substrate and the mask in a substantially vertical orientation. As used throughout the present disclosure, “substantially vertical” is understood particularly when referring to the substrate orientation, to allow for a deviation from the vertical direction or orientation of ±20° or below, e.g. of ±10° or below. This deviation can be provided for example because a substrate support with some deviation from the vertical orientation might result in a more stable substrate position. Further, fewer particles reach the substrate surface when the substrate is tilted forward. Yet, the substrate orientation, e.g., during the vacuum deposition process, is considered substantially vertical, which is considered different from the horizontal substrate orientation, which may be considered as horizontal ±20° or below.

The term “vertical direction” or “vertical orientation” is understood to distinguish over “horizontal direction” or “horizontal orientation”. That is, the “vertical direction” or “vertical orientation” relates to a substantially vertical orientation e.g. of the carriers, wherein a deviation of a few degrees, e.g. up to 10° or even up to 15°, from an exact vertical direction or vertical orientation is still considered as a “substantially vertical direction” or a “substantially vertical orientation”. The vertical direction can be substantially parallel to the force of gravity.

The embodiments described herein can be utilized for evaporation on large area substrates, e.g., for OLED display manufacturing. Specifically, the substrates for which the structures and methods according to embodiments described herein are provided, are large area substrates. For instance, a large area substrate or carrier can be GEN 4.5, which corresponds to a surface area of about 0.67 m² (0.73×0.92 m), GEN 5, which corresponds to a surface area of about 1.4 m² (1.1 m×1.3 m), GEN 7.5, which corresponds to a surface area of about 4.29 m² (1.95 m×2.2 m), GEN 8.5, which corresponds to a surface area of about 5.7 m² (2.2 m×2.5 m), or even GEN 10, which corresponds to a surface area of about 8.7 m² (2.85 m×3.05 m). Even larger generations such as GEN 11 and GEN 12 and corresponding surface areas can similarly be implemented. Half sizes of the GEN generations may also be provided in OLED display manufacturing.

According to some embodiments, which can be combined with other embodiments described herein, the substrate thickness can be from 0.1 to 1.8 mm. The substrate thickness can be about 0.9 mm or below, such as 0.5 mm. The term “substrate” as used herein may particularly embrace substantially inflexible substrates, e.g., a wafer, slices of transparent crystal such as sapphire or the like, or a glass plate. However, the present disclosure is not limited thereto, and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or below, such as 0.5 mm or below, wherein the flexibility of the substantially inflexible substrate is small in comparison to the flexible substrates.

FIGS. 6A and B show schematic views of a transport arrangement 600 for transporting a carrier 610, such as a mask carrier and/or a substrate carrier, in a vacuum system according to embodiments described herein. The transport arrangement 600 can be configured for transportation of the carrier through the opening between two adjacent pressure regions of the apparatuses and systems of the present disclosure.

As illustrated in FIG. 6A, according to an embodiment, the transport arrangement 600 for contactless transportation of a carrier 610 is provided. The carrier 610 can include a first magnet unit configured to magnetically interact with a guiding structure 670 of the vacuum system for providing a magnetic levitation force for levitating the carrier 610. In particular, the carrier 610 can include a first magnet unit, such as a first passive magnetic unit 650. The transport arrangement 600 can include a guiding structure 670 extending in a carrier assembly transportation direction, such as the transport direction 2, which can be a horizontal direction. The transport direction can be perpendicular to a vertical direction 1 and another horizontal direction 3. The guiding structure 670 can include a plurality of active magnetic units 675. The carrier 610 can be movable along the guiding structure 670. The first passive magnetic unit 650, e.g. a bar of ferromagnetic material, and the plurality of active magnetic units 675 of the guiding structure 670 can be configured for providing a first magnetic levitation force for levitating the carrier 610. The devices for levitating as described herein are devices for providing a contactless force to levitate e.g. the carrier 610.

In some implementations, the transport arrangement 600 may further include a drive structure 680. The drive structure 680 can include a plurality of further magnet units, such as further active magnetic units. The carrier 610 can include a second magnet unit configured to magnetically interact with the drive structure 680 of the vacuum system. In particular, the carrier 610 can include the second magnet unit, such as a second passive magnetic unit 660, e.g. a bar of ferromagnetic material to interact with the further active magnetic units 685 of the drive structure 680.

FIG. 6B shows another side view of the transport arrangement 600. In FIG. 6B, an active magnetic unit of the plurality of active magnetic units 675 is shown. The active magnetic unit provides a magnetic force interacting with the first passive magnetic unit 650 of the carrier 610. For example, the first passive magnetic unit 650 can be a rod of a ferromagnetic material. A rod can be a portion of the carrier 610 that is connected to a support structure 612. The support structure 612 can be provided by the body of the carrier 610. The rod or the first passive magnetic unit, respectively, may also be integrally formed with the support structure 612 for supporting the substrate 10. The carrier 610 can further include the second passive magnetic unit 660, for example a further rod. The further rod can be connected to the carrier 610. The rod or the second passive magnetic unit, respectively, may also be integrally formed with the support structure 612.

The terminology of a “passive” magnetic unit is used herein to distinguish from the notion of an “active” magnetic unit. A passive magnetic unit may refer to an element with magnetic properties which are not subject to active control or adjustment, at least not during operation of the transport arrangement 600. For example, the magnetic properties of a passive magnetic unit, e.g. the rod or the further rod of the carrier, are not subject to active control during movement of the carrier through the vacuum chamber or vacuum system in general. According to some embodiments, which can be combined with other embodiments described herein, a controller of the transport arrangement 600 is not configured to control a passive magnetic unit. A passive magnetic unit may be adapted for generating a magnetic field, e.g. a static magnetic field. A passive magnetic unit may not be configured for generating an adjustable magnetic field. A passive magnetic unit may be a magnetic material, such as a ferromagnetic material, a permanent magnet or may have permanent magnetic properties.

Compared to a passive magnetic unit, an active magnetic unit offers more flexibility and precision in light of the adjustability and controllability of the magnetic field generated by the active magnetic unit. According to embodiments described herein, the magnetic field generated by an active magnetic unit may be controlled to provide for an alignment of the carrier 610. For example, by controlling the adjustable magnetic field, a magnetic levitation force acting on the carrier 610 may be controlled with high accuracy, thus allowing for a contactless alignment of the carrier and, thus, a substrate, by the active magnetic unit.

According to embodiments described herein, the plurality of active magnetic units 675 provides for a magnetic force on the first passive magnetic unit 650 and thus, the carrier 610. The plurality of active magnetic units 675 levitates the carrier 610. The further active magnetic units 685 can drive the carrier 610 within the vacuum chamber, for example along the transport direction 2. The plurality of further active magnetic units 685 forms the drive structure for moving the carrier 610 in the transport direction 2 while being levitated by the plurality of active magnetic units 675 located above the carrier 610. The further active magnetic units 685 can interact with the second passive magnetic unit 660 to provide a force along the transport direction 2. For example, the second passive magnetic unit 660 can include a plurality of permanent magnets arranged with an alternating polarity. The resulting magnetic fields of the second passive magnetic unit 660 can interact with the plurality of further active magnetic units 685 to move the carrier 610 while being levitated.

In order to levitate the carrier 610 with the plurality of active magnetic units 675 and/or to move the carrier 610 with the plurality of further active magnetic units 685, the active magnetic units can be controlled to provide adjustable magnetic fields. The adjustable magnetic field may be a static or a dynamic magnetic field. According to embodiments, which can be combined with other embodiments described herein, an active magnetic unit is configured for generating a magnetic field for providing a magnetic levitation force extending along a vertical direction 1. According to other embodiments, which can be combined with further embodiments described herein, an active magnetic unit may be configured for providing a magnetic force extending along a transversal direction. An active magnetic unit, as described herein, may be or include an element selected from the group consisting of an electromagnetic device, a solenoid, a coil, a superconducting magnet, or any combination thereof.

Embodiments described herein relate to contactless levitation, transportation and/or alignment of a carrier, a substrate and/or a mask. The disclosure refers to a carrier, which may include one or more elements of the group consisting of: a carrier supporting a substrate, a carrier without a substrate, a substrate, or a substrate supported by a support. The term “contactless” as used throughout the present disclosure can be understood in the sense that a weight of e.g. the carrier and the substrate is not held by a mechanical contact or mechanical forces, but is held by a magnetic force. Specifically, the carrier is held in a levitating or floating state using magnetic forces instead of mechanical forces. As an example, the transport arrangement described herein may have no mechanical devices, such as a mechanical rail, supporting the weight of the carrier. In some implementations, there can be no mechanical contact between the carrier and the rest of the apparatus at all during levitation, and for example movement, of the carrier in the vacuum system.

According to embodiments of the present disclosure, levitating or levitation refers to a state of an object, wherein the objects floats without mechanical contact or support. Further, moving an object refers to providing a driving force, e.g. a force in a direction different from a levitation force, wherein the object is moved from one position to another, different position. For example, an object such as a carrier can be levitated, i.e. by a force counteracting gravity, and can be moved in a direction different from a direction parallel to gravity while being levitated.

The contactless levitation, transportation and/or alignment of the carrier according to embodiments described herein is beneficial in that no particles are generated due to a mechanical contact between the carrier and sections of the transport arrangement 600, such as mechanical rails, during the transport or alignment of the carrier. Accordingly, embodiments described herein provide for an improved purity and uniformity of the layers deposited on the substrate, in particular since a particle generation is minimized when using the contactless levitation, transportation and/or alignment.

A further advantage, as compared to mechanical devices for guiding the carrier, is that embodiments described herein do not suffer from friction affecting the linearity and/or precision of the movement of the carrier. The contactless transportation of the carrier allows for a frictionless movement of the carrier, wherein an alignment of the carrier assembly relative to a mask can be controlled and maintained with high precision. Yet further, the levitation allows for fast acceleration or deceleration of the carrier speed and/or fine adjustment of the carrier speed.

Further, the material of mechanical rails typically suffers from deformations, which may be caused by evacuation of a chamber, by temperature, usage, wear, or the like. Such deformations affect the position of the carrier, and hence affect the quality of the deposited layers. In contrast, embodiments described herein allow for a compensation of potential deformations present in e.g. the guiding structure described herein. In view of the contactless manner in which the carrier is levitated and transported, embodiments described herein allow for a contactless alignment of the carrier. Accordingly, an improved and/or more efficient alignment of the substrate relative to the mask can be provided.

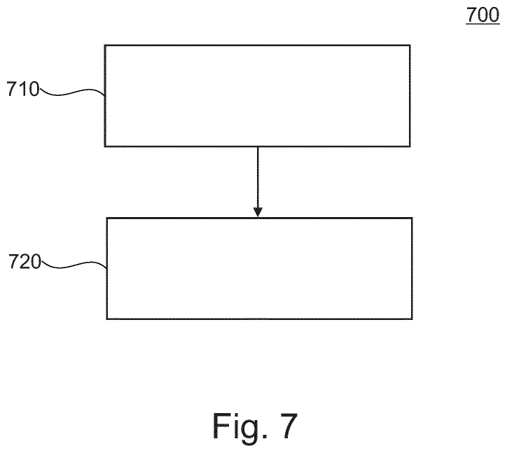

FIG. 7 shows a flowchart of a method 700 for sealing an opening connecting two adjacent pressure regions according to embodiments described herein. The method 700 can be implemented using the apparatuses and systems described herein.

The method 700 includes, in block 710, changing a magnetization of one or more first permanent magnets to a first magnetization for providing a magnetic force to close the opening. The opening can connect the two pressure regions, such as the first pressure region and the second pressure region, such that e.g. a carrier can be transferred between the first pressure region and the second pressure region. The carrier can be a mask carrier and/or a substrate carrier. In some implementations, the method 700 further includes, in block 720, changing the magnetization of the one or more first permanent magnets to a second magnetization different from the first magnetization for releasing the magnetic force. As an example, the changing the magnetic force can include a reversing of a polarity of one or more first permanent magnets using, for example, an electric pulse.

According to embodiments described herein, the method for sealing an opening connecting two pressure regions can be conducted using computer programs, software, computer software products and the interrelated controllers, which can have a CPU, a memory, a user interface, and input and output devices being in communication with the corresponding components of the apparatus.

The present disclosure provides an opening connecting two adjacent pressure regions, wherein the opening is closeable by changing a magnetization of one or more first permanent magnets. As an example, a sealing device can cover the opening, wherein the sealing device can be magnetically held at the opening to seal the opening. The magnetic sealing can reduce a number of mechanically movable parts in the vacuum system. A generation of particles due to such mechanically movable parts can be reduced and e.g. a quality of the material layers deposited on the substrate can be improved. Further, a reliable closing of the opening can be provided also in case of a power failure, because the opening is sealed by a magnetic force generated by permanent magnets. No external power may be needed for maintaining the sealed state.

While the foregoing is directed to embodiments of the disclosure, other and further embodiments of the disclosure may be devised without departing from the basic scope thereof, and the scope thereof is determined by the claims that follow.

1. An apparatus for vacuum processing of a substrate, comprising:
a first pressure region, a second pressure region, and an opening between the first pressure region and the second pressure region;
a closing arrangement for closing the opening, including:
one or more first permanent magnets and one or more second permanent magnets; and
a magnet device configured to change a magnetization of the one or more first permanent magnets; and
a sealing device including a magnetic material and configured for closing the opening.

2. The apparatus of claim 1, wherein a magnetic field generated by the closing arrangement is configured to act on the magnetic material to provide a magnetic force attracting the sealing device towards the opening.

3. The apparatus of claim 2, wherein the closing arrangement is configured to magnetically hold the sealing device at the opening.

4. The apparatus of claim 1, wherein the one or more first permanent magnets include a soft magnetic material or a semi-hard magnetic material, and wherein the one or more second permanent magnets include a hard magnetic material.

5. The apparatus of claim 1, wherein the magnet device includes a winding provided at least partially around the one or more first permanent magnets.

6. The apparatus of claim 1, wherein a direction of a magnetization of the one or more first permanent magnets is switchable by an electric pulse provided to the magnet device, wherein a polarity of the one or more first permanent magnets is reversible by the electric pulse.

7. The apparatus of claim 1, further including a holding surface at the opening, wherein the closing arrangement is switchable between a chucking state and a releasing state,
wherein, in the chucking state, the closing arrangement generates a first external magnetic field at the holding surface, and
wherein, in the releasing state, the closing arrangement generates no external magnetic field or a second external magnetic field smaller than the first external magnetic field at the holding surface.

8. The apparatus of claim 1, including a first vacuum chamber and a second vacuum chamber, wherein the first pressure region is provided by the first vacuum chamber and the second pressure region is provided by the second vacuum chamber.

9. The apparatus of claim 1, including a first vacuum chamber providing the first pressure region and the second pressure region, wherein the vacuum chamber includes a partition separating the first pressure region and the second pressure region from each other, and wherein the opening is provided in the partition.

10. The apparatus of claim 1, including a first vacuum chamber providing the first pressure region, wherein the second pressure region is a region of atmospheric pressure.

11. The apparatus of claim 8, wherein at least one of the first vacuum chamber and the second vacuum chamber are selected from the group consisting of a processing vacuum chamber, a transit module, a routing module, a maintenance vacuum chamber, a load lock chamber, a buffer chamber, a swing module, and a storage chamber.

12. The apparatus of claim 1, wherein the opening is configured for a passage of a mask, a mask carrier, a substrate, a substrate carrier, and any combination thereof.

13. A system for the manufacture of devices having organic materials, comprising:
an apparatus for vacuum processing of a substrate, comprising:
a first pressure region, a second pressure region, and an opening between the first pressure region and the second pressure region;
a closing arrangement for closing the opening, including:
one or more first permanent magnets and one or more second permanent magnets; and
to change a magnetization of the one or more first permanent magnets; and
a sealing device including a magnetic material and configured for closing the opening;
the system further comprising:
a transport arrangement configured for contactless transportation of at least one of a substrate carrier and a mask carrier through the opening.

14. A method for sealing an opening connecting two pressure regions, comprising:
changing a magnetization of one or more first permanent magnets to a first magnetization for providing a magnetic force to close the opening, wherein a magnetic field generated by the one or more first permanent magnets and one or more second permanent magnets acts on a magnetic material of a sealing device to provide the magnetic force attracting the sealing device towards the opening.

15. The method of claim 14, further including:
changing the magnetization of the one or more first permanent magnets to a second magnetization for releasing the magnetic force.

16. The apparatus of claim 2, wherein the one or more first permanent magnets include a soft magnetic material or a semi-hard magnetic material, and wherein the one or more second permanent magnets include a hard magnetic material.

17. The apparatus of claim 3, wherein the one or more first permanent magnets include a soft magnetic material or a semi-hard magnetic material, and wherein the one or more second permanent magnets include a hard magnetic material.

18. The apparatus of claim 6, further including a holding surface at the opening, wherein the closing arrangement is switchable between a chucking state and a releasing state,
wherein, in the chucking state, the closing arrangement generates a first external magnetic field at the holding surface, and
wherein, in the releasing state, the closing arrangement generates no external magnetic field or a second external magnetic field smaller than the first external magnetic field at the holding surface.

19. The system of claim 13, further including a holding surface at the opening, wherein the closing arrangement is switchable between a chucking state and a releasing state,
wherein, in the chucking state, the closing arrangement generates a first external magnetic field at the holding surface, and
wherein, in the releasing state, the closing arrangement generates no external magnetic field or a second external magnetic field smaller than the first external magnetic field at the holding surface.
